(19) United States
(12) Patent Application Publication
(10) Pub. No.: US 2007/0202695 A1
(43) Pub. Date: Aug. 30, 2007

(54) Method for fabricating a semiconductor device

(75) Inventors: Kazuo Kawamura, Kawasaki (JP); Hiroyuki Ohta, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/504,585

(22) Filed: Aug. 16, 2006

(30) Foreign Application Priority Data
Feb. 27, 2006 (JP) 2006-051108

(51) Int. Cl. H01L 21/44

(52) U.S. Cl. 438/664; 438/682; 438/694

(57) ABSTRACT

A semiconductor device fabrication method that prevents an increase in junction leakage current in a semiconductor device in which nickel silicide is used as a gate electrode, a source electrode, and a drain electrode. A native oxide film formed on the surface of a semiconductor substrate where a gate region, a source region, and a drain region are formed is removed by sputter etching in which control is exercised in order to suppress the penetration of the semiconductor substrate by ions to 2 nm or less from the surface. A film of nickel or a nickel compound is formed on the surface of the semiconductor substrate where the native oxide film is removed, and nickel silicide is formed in the gate region, the source region, and the drain region by anneal. As a result, the formation of a spike is prevented in the gate region, the source region, and the drain region and a leakage current is decreased.

### CROSS-REFERENCE TO RELATED APPLICATIONS

This application is based upon and claims the benefits of priority from the prior Japanese Patent Application No. 2006-051108, filed on Feb. 27, 2006, the entire contents of which are incorporated herein by reference.

### BACKGROUND OF THE INVENTION

(1) Field of the Invention

This invention relates to a method for fabricating a semiconductor device, and more particularly, to a method for fabricating a semiconductor device in which nickel silicide is used as a gate electrode, a source electrode, and a drain electrode.

(2) Description of the Related Art

Cobalt silicide has conventionally been adopted as a gate electrode, a source electrode, and a drain electrode in a metal oxide semiconductor field effect transistor (MOSFET). On the other hand, nickel monosilicide (NiSi) can be formed at a low temperature and variation in the resistance of thin wires is small. Attention is newly riveted on nickel monosilicide because of these characteristics.

With miniaturization of semiconductor devices and an increase in the integration levels of semiconductor devices, the junction depth of source/drain regions becomes shallow (<80 nm), the thickness of silicide films used as electrodes becomes thin (<20 nm), gate length becomes short (<50 nm), and transistor width W in complementary metal oxide semiconductors (CMOSes) or random access memories (RAMs) becomes smaller than or equal to 1 μm. FIG. 34 shows the Ion-Ioff characteristic of a pMOS. As can be seen from FIG. 34, if transistor width W in a p-channel metal oxide semiconductor (PMOS) is small, a leakage current (OFF-state current (Ioff)) increases rapidly in respect to an ON-state current (Ion).

In addition, recent researches have shown that if NiSi is used in a source region, a gate region, and a drain region and the transistor width W is smaller than or equal to 1 μm, abnormal diffusion of nickel (Ni), such as high-resistance nickel disilicide (NiSi₂) spike or agglomeration of NiSiₓ, induces a tunnel current which contributes to an increase in Ioff especially in a pMOS.

In the conventional method for fabricating a logic device, an Ni film is deposited after diluted hydrofluoric acid treatment in a salicide process. After the diluted hydrofluoric acid treatment is performed, a silicon (Si) substrate is left in air. A native oxide film is formed on the surface of the Si substrate in this process. This causes abnormal diffusion of nickel (see P. S. Lee, D. Mangelinck, K. L. Pey, J. Ding, J. Dai, C. S. Ho, and A. See, Microelectron. Eng. 51, 583 (2000)). FIG. 35 is a schematic view showing the occurrence of abnormal diffusion of nickel. A native oxide film (not shown) is formed on an Si substrate 600 and a gate region 601. When an Ni film (not shown) is deposited on the native oxide film, Ni cannot be supplied fully to the Si substrate 600 or the gate region 601, so not only nickel monosilicide (NiSi) 604 but also nickel disilicide (NiSi₂) 605 is formed in the gate region 601 and a source region 603. The NiSi₂ 605 causes abnormal diffusion of nickel, resulting in an increase in leakage current. The following technique for removing a native oxide film is conventionally known as one of measures to solve this problem. Before deposition of an Ni film, argon (Ar) ions are sputtered on the surface of an Si substrate where a native oxide film is formed, and then activation anneal is performed (see Japanese Unexamined Patent Publication No. 11-233455).

With the conventional Ar-ion sputter etching, however, comparatively high power Ar ions are outputted for generating plasma. FIG. 36 shows the relationship between sputter etching power and a leakage current. As can be seen from FIG. 36, high power sputter etching increases a leakage current. Excessive damage is done to an Si substrate, so a junction leakage current increases.

### SUMMARY OF THE INVENTION

The present invention was made under the background circumstances described above. An object of the present invention is to provide a semiconductor device fabrication method which can prevent an increase in junction leakage current in a semiconductor device in which nickel silicide is used as a gate electrode, a source electrode, and a drain electrode.

In order to achieve the above object, there is provided a method for fabricating a semiconductor device in which nickel silicide is used as a gate electrode, a source electrode, and a drain electrode, comprising the steps of removing by sputter etching a native oxide film formed on a surface of a semiconductor substrate where a gate region, a source region, and a drain region are formed, the suputter etching being controlled so as to suppress penetration of the semiconductor substrate by ions to 2 nm or less from the surface; forming a film of nickel or a nickel compound on the surface from which the native oxide film is removed; and forming nickel silicide in the gate region, the source region, and the drain region by anneal.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIGS. 1A to 1D are schematic views of a method for fabricating a semiconductor device according to the present invention.

FIG. 2A to 19 are sectional views showing respective steps for fabricating a semiconductor device according to a first embodiment of the present invention.

FIG. 20 is a schematic sectional view showing a gate edge enhancement monitor.

FIG. 21 shows results obtained by measuring a junction leakage current in gate edge enhancement monitors.

FIG. 22 shows results obtained by measuring sheet resistance of thin wires.

FIGS. 23 to 31 are sectional views showing respective steps for fabricating a semiconductor device according to a second embodiment of the present invention.

FIG. 32 is a schematic view showing a semiconductor device fabrication apparatus.

FIG. 33 shows the mechanism of a sputter etching chamber.

FIG. 34 shows the Ion-Ioff characteristic of a pMOS.

FIG. 35 is a schematic view showing the occurrence of abnormal diffusion of nickel.

FIG. 36 shows the relationship between sputter etching power and a leakage current.

### DESCRIPTION OF THE PREFERRED EMBODIMENTS

Embodiments of the present invention will now be described with reference to the drawings.

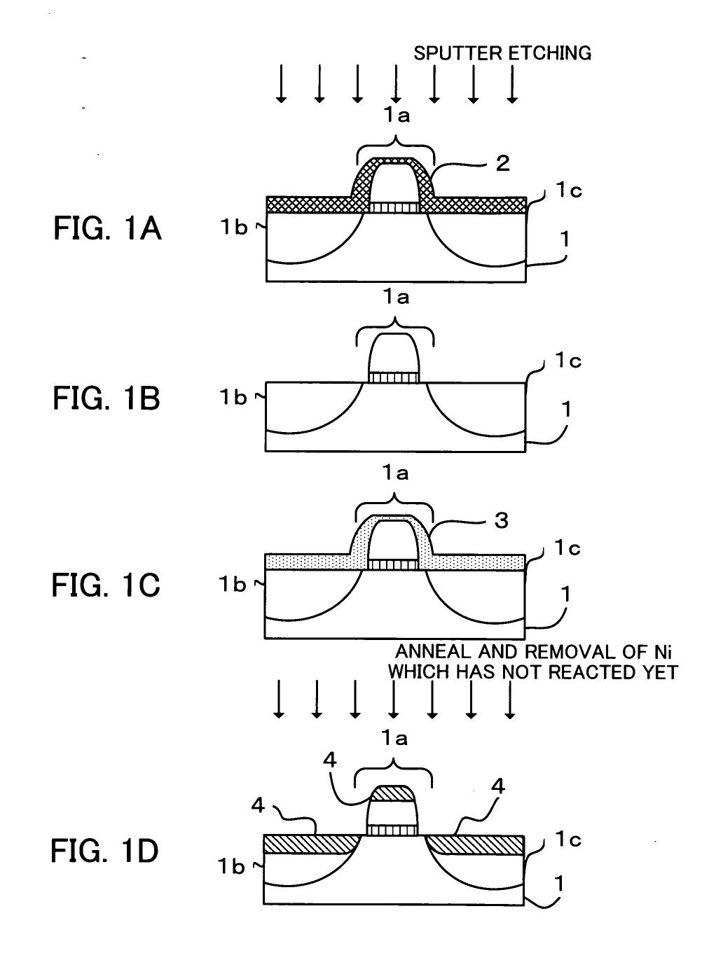

FIG. 1 is a schematic view of a method for fabricating a semiconductor device, according to the present invention.

In the process for fabricating a semiconductor device in which nickel silicide is used as a gate electrode, a source electrode, and a drain electrode, a native oxide film 2 is formed of oxygen molecules, hydrogen molecules, and the like contained in air on an Si substrate 1 where a gate region 1a, a source region 1b, and a drain region 1c are formed (FIG. 1A). It is the characteristic of the method for fabricating a semiconductor device according to the present invention that the native oxide film 2 is removed by sputter etching in which control is exercised in order to suppress the penetration of the Si substrate 1 by ions to 2 nm or less from the surface (FIG. 1B). By suppressing the penetration of the Si substrate 1 by ions to 2 nm or less from the surface by the sputter etching, ions which penetrate into the Si substrate 1 are made amorphous and damage to the Si substrate 1 can be reduced (detailed sputtering conditions and the like will be described later). After the native oxide film 2 is removed, an Ni (or a nickel compound) film 3 is formed on the Si substrate 1 (FIG. 1C). At this time the Si substrate 1 is not exposed to air. Anneal treatment is performed to form NiSi 4 which functions as electrodes in the gate region 1a, the source region 1b, and the drain region 1c, and the Ni film 3 which has not reacted yet is removed (FIG. 1D). A contact plug, a wiring, and the like are then formed.

As stated above, by adopting the semiconductor device fabrication method according to the present invention shown in FIGS. 1A to 1D, the native oxide film 2 formed on the Si substrate 1 can be removed before the formation of the Ni film 3 and damage to the Si substrate 1 can be minimized. As a result, a junction leakage current can be decreased.

Embodiments of the present invention will now be described in detail.

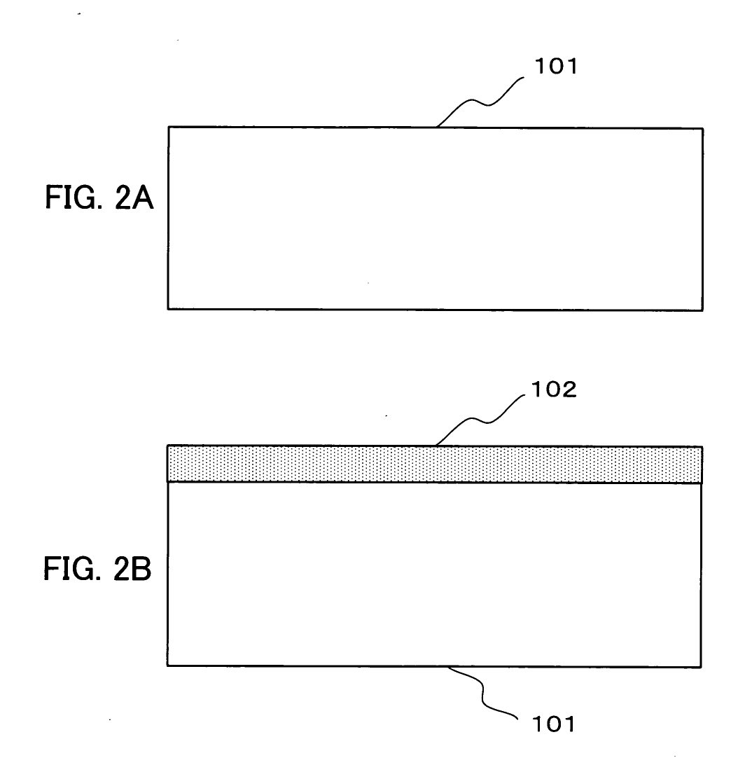

Each of FIGS. 2A through 19 is a sectional view showing a step in a semiconductor device fabrication method according to a first embodiment of the present invention.

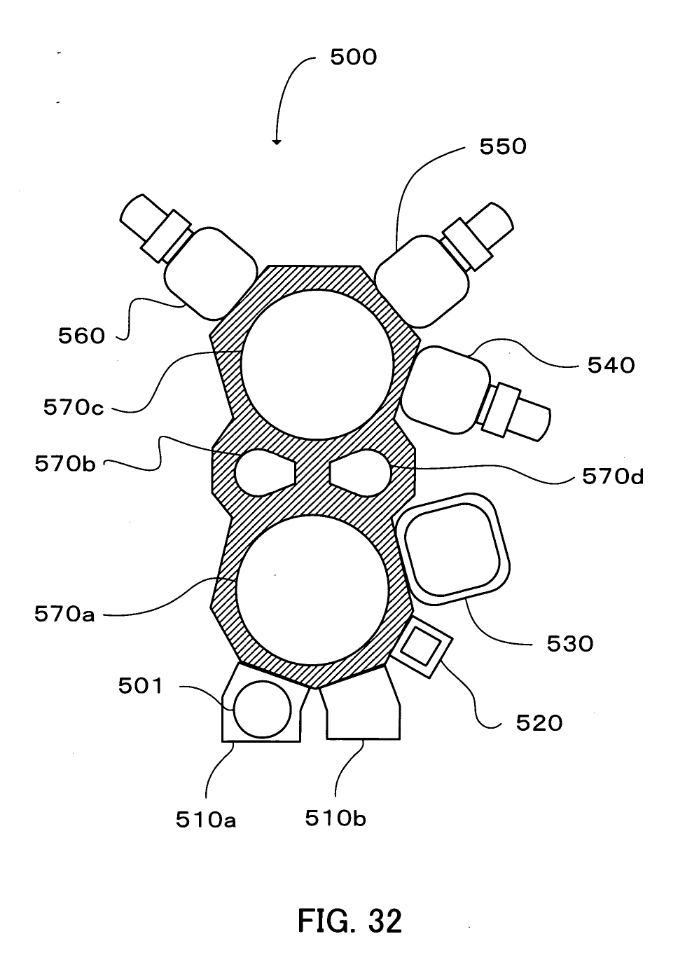

FIG. 32 is a schematic view showing a semiconductor device fabrication apparatus. A fabrication apparatus 500 shown in FIG. 32 includes a wafer alignment chamber 520, an Ar sputter etching chamber 530, an Ni chamber 540, an anneal chamber 550, and a cap film chamber 560 for performing the following salicide process on a wafer 501 introduced into a vacuum system from a lord lock (LL) 510a or an LL 510b. The wafer 501 is transported from chamber to chamber through transfer sections 570a, 570b, 570c, and 570d in which air is evacuated, so the wafer 501 which is in process is not exposed to air. The wafer 501 processed with the fabrication apparatus 500 having the above structure is taken out from the LL 510a or the LL 510b.

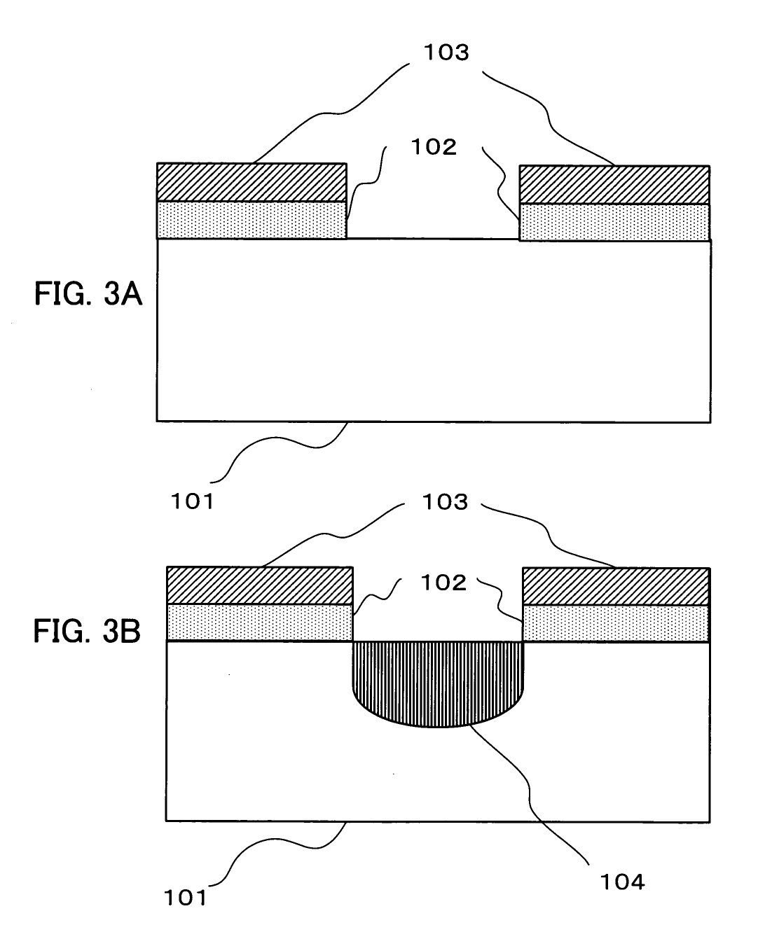

In the semiconductor device fabrication method according to the first embodiment of the present invention, a p-type Si (100) substrate 101 is cleaned first by an ammonia hydrogen peroxide (H₂O₂) mixture solution (FIG. 2A). An oxide film 102 with a thickness of about 50 nm is made to grow on the p-type Si (100) substrate 101 cleaned by thermal oxidation (FIG. 2B). The p-type Si (100) substrate 101 is coated with a photoresist, a photoresist pattern 103 is formed by patterning, and the oxide film 102 is etched (FIG. 3A). To form a p-well 104, boron (B) ions are implanted with a dose of 1E13 ions/cm² at an energy of 120 keV (to form an n-well, phosphorus (P) ions are implanted with a dose of 1E13 ions/cm² at an energy of 300 keV) and activation anneal is performed (FIG. 3B).

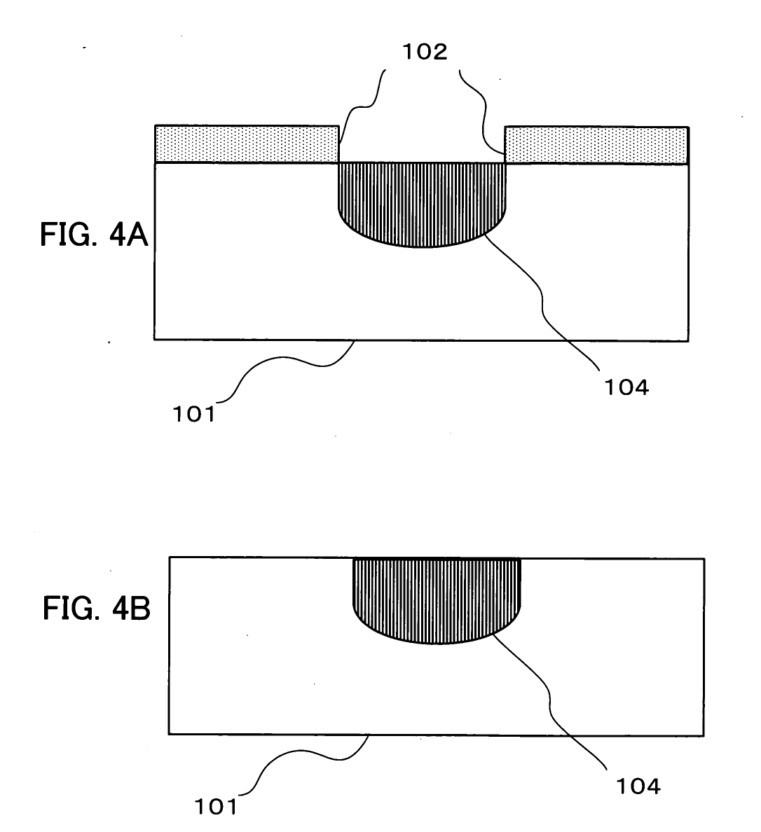

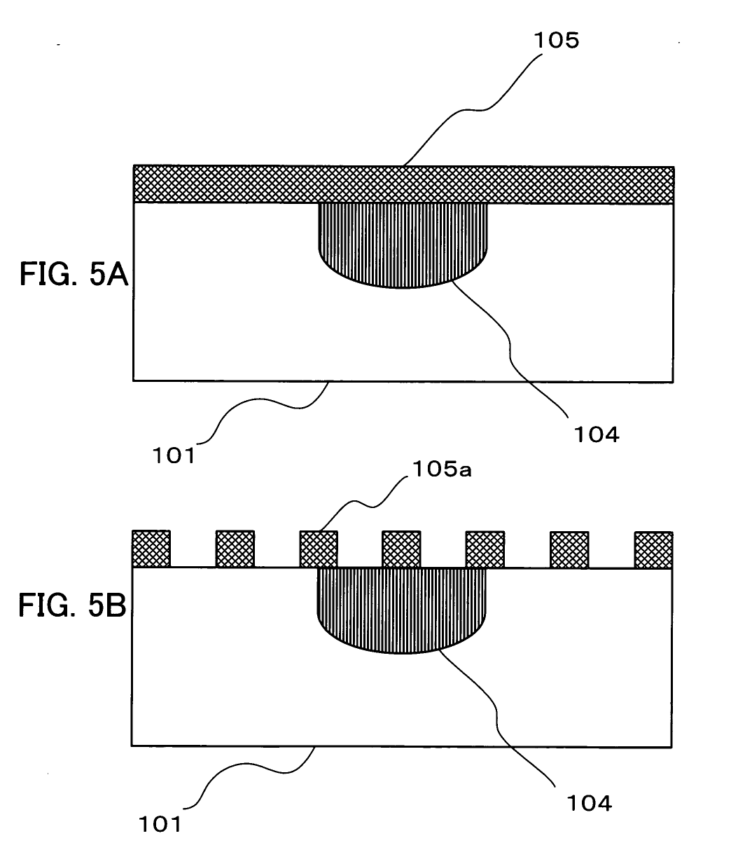

The photoresist pattern 103 is then removed (FIG. 4A) and the oxide film 102 is removed (FIG. 4B). A silicon nitride (SiN) film 105 with a thickness of 50 nm is deposited on the p-type Si (100) substrate 101 and the p-well 104 by a chemical vapor deposition (CVD) method (FIG. 5A). After the SiN film 105 is deposited, the p-type Si (100) substrate 101 is coated with a photoresist (not shown), patterning is performed, and the SiN film 105 is etched. By doing so, an SiN pattern 105a is formed. After the SiN pattern 105a is formed, the photoresist is removed (FIG. 5B).

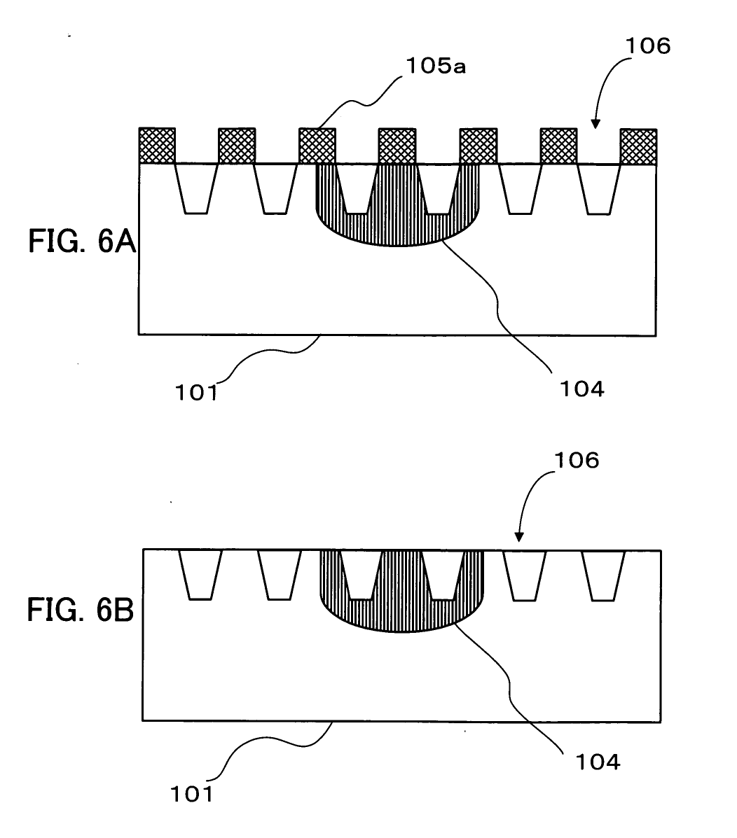

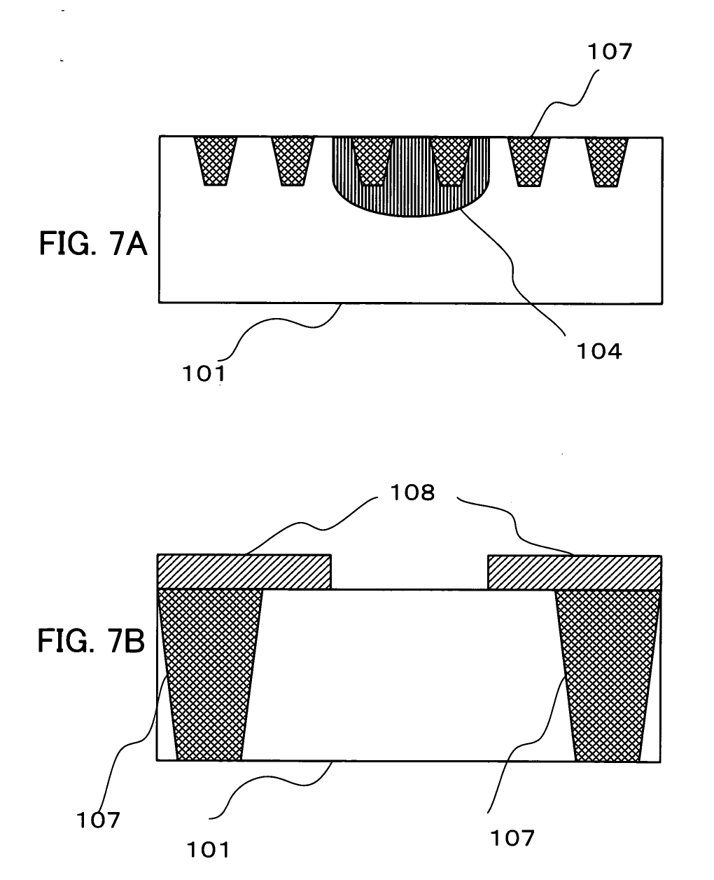

After the photoresist is removed, an STI burying hole 106 is made by etching (FIG. 6A). After the STI burying hole 106 is made, the SiN pattern 105a is removed (FIG. 6B). An oxide film is buried in the STI burying hole 106 by the CVD method and is planarized by a chemical mechanical polishing (CMP) method. By doing so, STI 107 is formed (FIG. 7A). After the STI 107 is formed, the p-type Si (100) substrate 101 is coated with a photoresist, patterning is performed, and a photoresist pattern 108 is formed (FIG. 7B). In FIG. 7B, a p-well 104 portion after the patterning is enlarged.

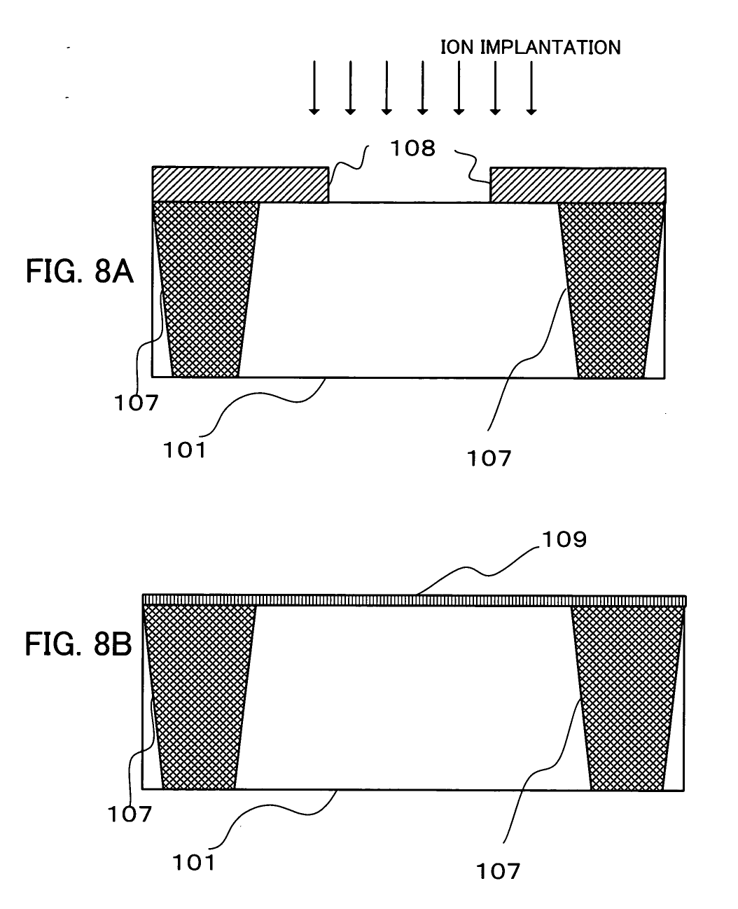

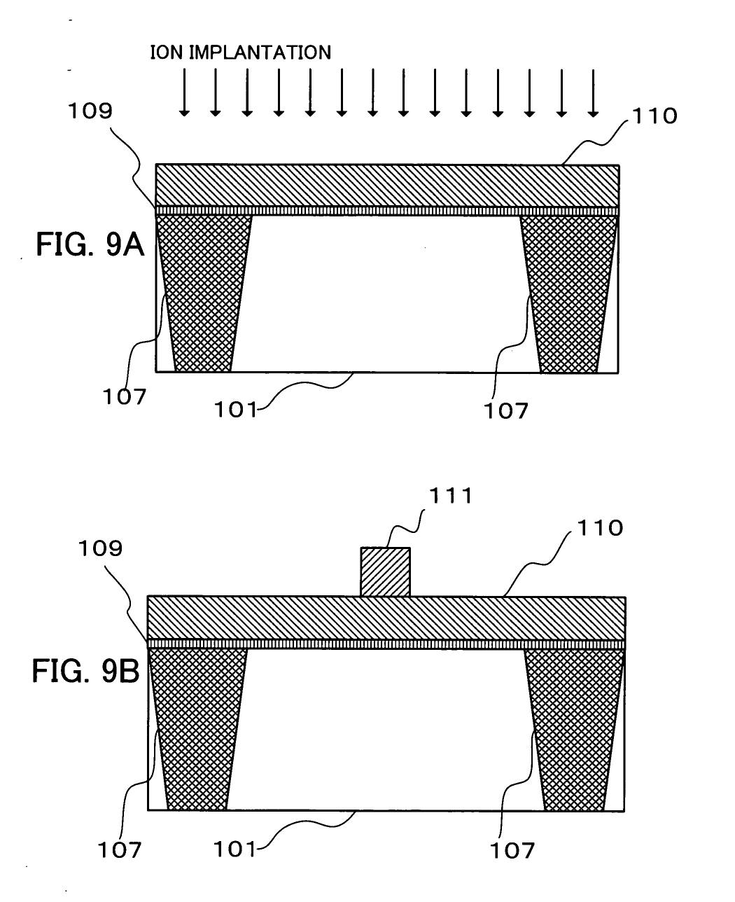

After the patterning is performed, ion implantation is performed to form a channel. To form an n-channel metal oxide semiconductor (nMOS), B ions are implanted with a dose of 1E13 ions/cm² at an energy of 15 keV. To form a pMOS, arsenic (As) ions are implanted with a dose of 1E13 ions/cm² at an energy of 80 keV (FIG. 8A). After the ion implantation is performed, the photoresist pattern 108 is removed, activation anneal is performed at a temperature of 950° C. for 10 seconds, and a gate insulating film 109 with a thickness of 2 nm is formed by the CVD method (FIG. 8B). After the gate insulating film 109 is formed, polycrystalline silicon 110 with a thickness of 100 nm is deposited and ion implantation (P ions are implanted with a dose of 1E16 ions/cm² at an energy of 10 keV for forming an nMOS and B ions are implanted with a dose of 5E15 ions/cm² at an energy of 5 keV for forming a PMOS) is performed (FIG. 9A). To form a gate after the ion implantation, the p-type Si (100) substrate 101 is coated with a photoresist and a photoresist pattern 111 is formed (FIG. 9B).

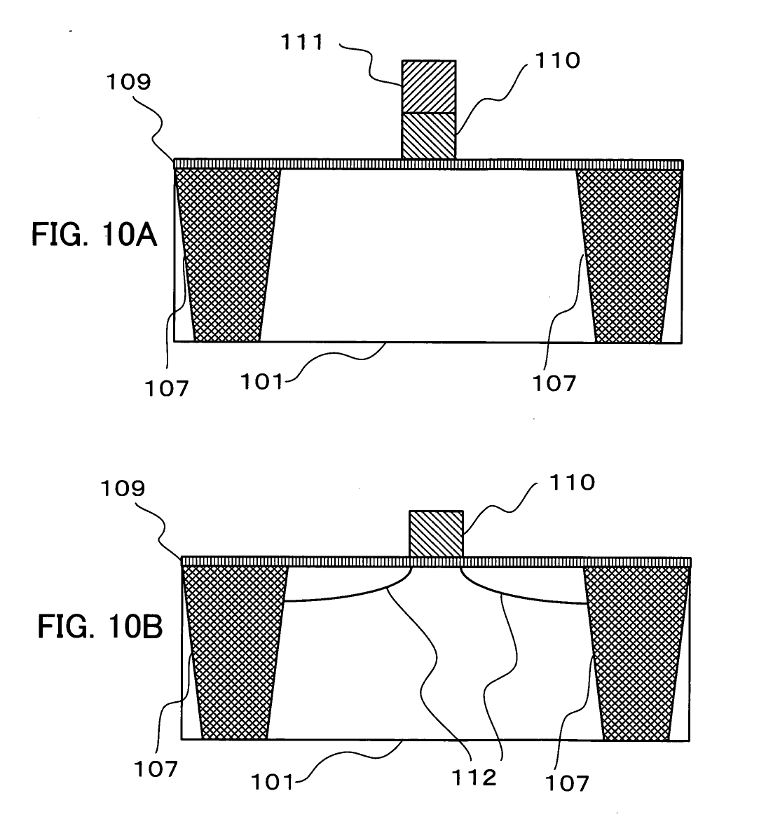

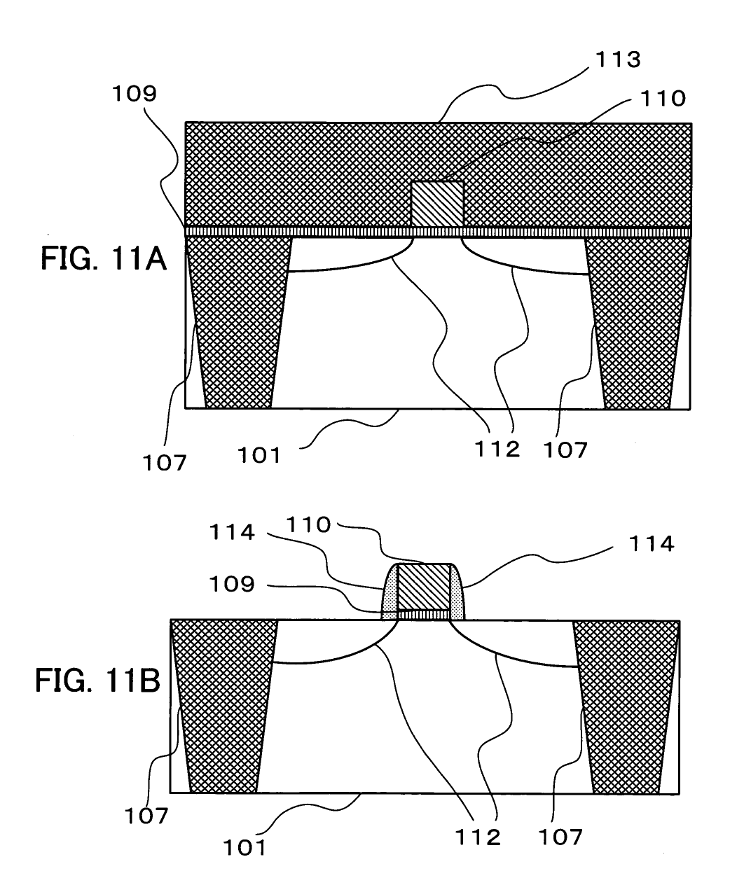

Etching is performed with the photoresist pattern 111 formed as a mask to form the gate (FIG. 10A). The photoresist pattern 111 is removed. To form extensions 112, ion implantation (As ions are implanted with a dose of 1E15 ions/cm² at an energy of 1 keV for forming an nMOS and B ions are implanted with a dose of 1E15 ions/cm² at an energy of 0.5 keV for forming a pMOS) is performed (FIG. 10B). After the extensions 112 are formed, an oxide film 113 with a thickness of 100 nm is deposited by the CVD method (FIG. 11A). Side wall spacers 114 are formed by performing reactive ion etching (RIE) on the oxide film 113 deposited (FIG. 11B).

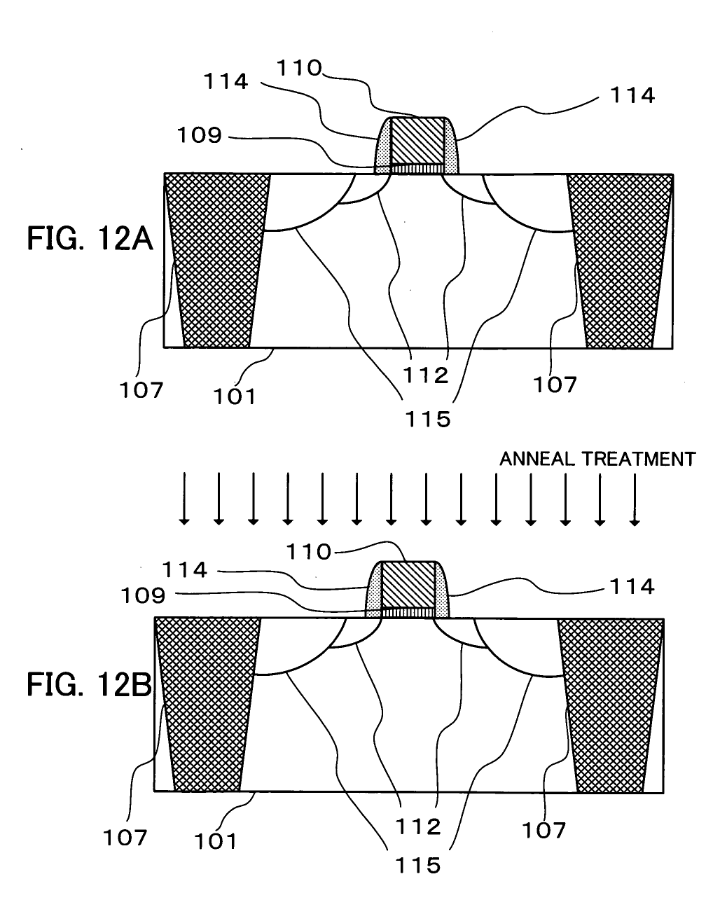

To form source/drain regions 115, ion implantation (P ions are implanted with a dose of 1E16 ions/cm² at an energy of 8 keV for forming an nMOS and B ions are implanted with a dose of 5E15 ions/cm² at an energy of 5 keV for forming a pMOS) is performed (FIG. 12A). Activation anneal is then performed (FIG. 12B).

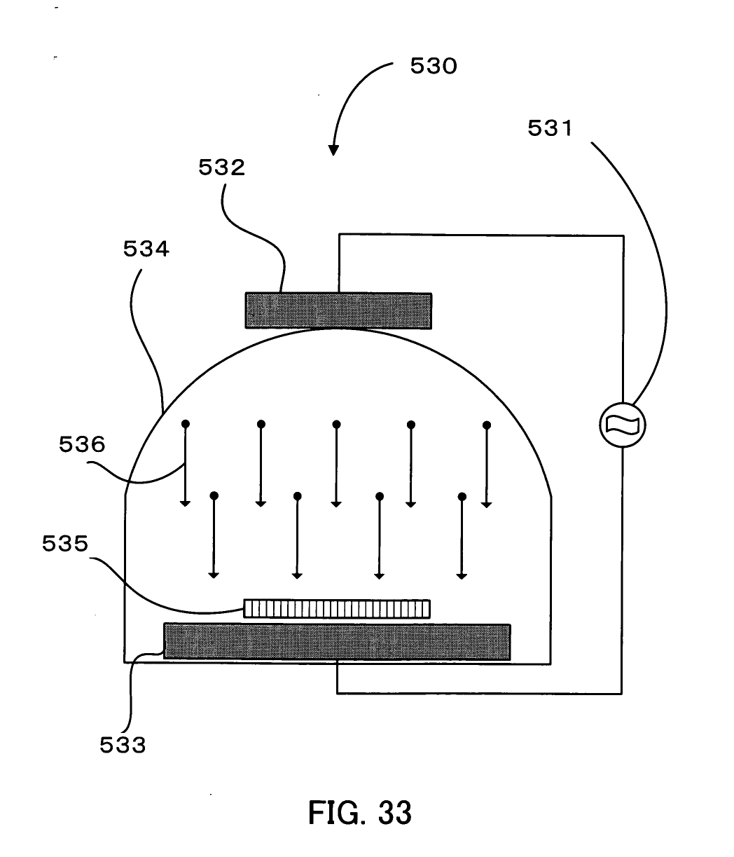

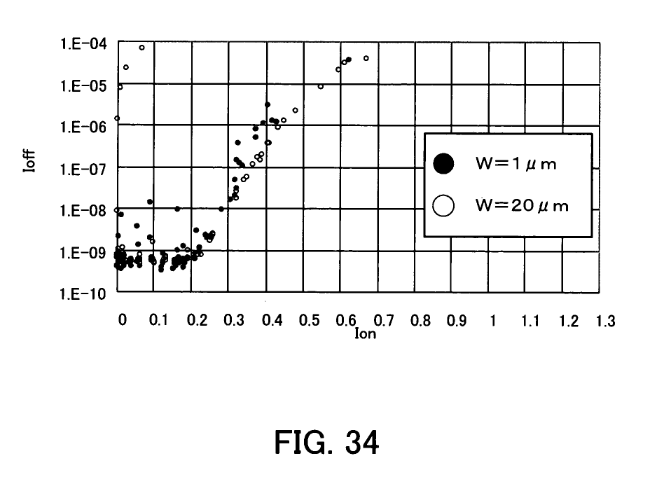

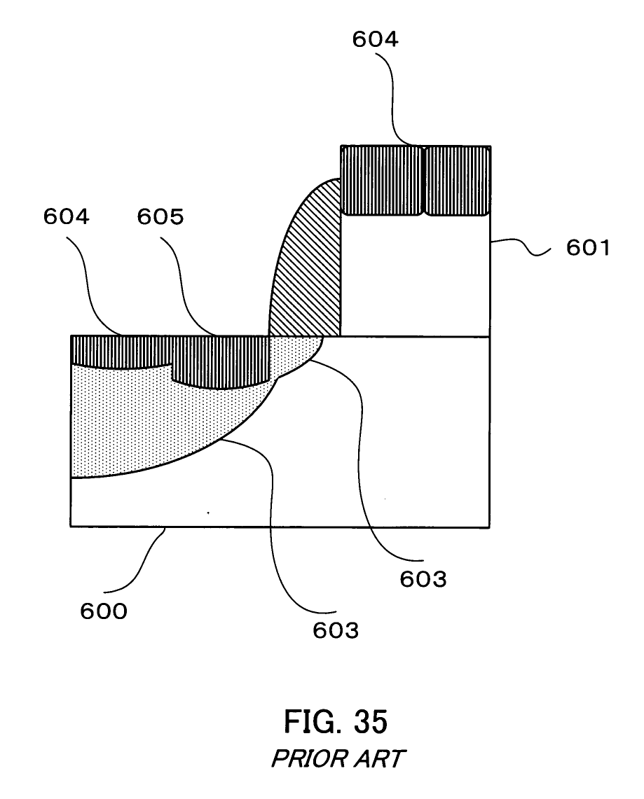

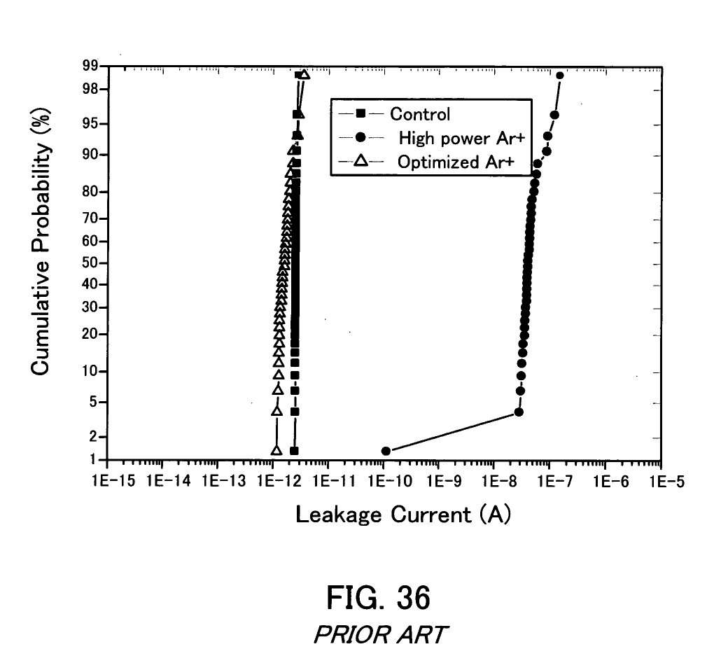

For the sake of simplicity only the salicide process will be described. FIG. 33 shows the mechanism of the sputter etching chamber. FIG. 33 will be described first in brief. When low-frequency electric power and high-frequency electric power are supplied to electrodes 532 and 533 from a power source 531, an inert gas in a chamber 534 is activated, plasma is generated, and ions 536 collide with a wafer 535. As a result, the surface of the wafer 535 can be cleaned.

The wafer after the activation anneal shown in FIG. 12B is transported into the above chamber 534 and a native oxide film (not shown) formed on the wafer is removed by sputter etching.

As stated above, by suppressing the penetration of the Si substrate by ions to 2 nm or less from the surface by the sputter etching, ions which penetrate into the Si substrate are made amorphous and damage to the Si substrate can be reduced. Therefore, the TRIM software (freeware) was used for doing simulations of ion implantation. By doing so, the type of an inert gas, pressure, time, low-frequency electric power, and high-frequency electric power suitable for the sputter etching were examined. Results were as follows. An inert gas suitable for the sputter etching is Ar (low-frequency electric power is 0.1 to 0.4 W/cm² and high-frequency electric power is 1.5 to 2.6 W/cm²), krypton (Kr) (low-frequency electric power is 0.1 to 0.4 W/cm² and high-frequency electric power is 1.5 to 2.6 W/cm²), xenon (Xe) (low-frequency electric power is 0.1 to 0.4 W/cm² and high-frequency electric power is 1.5 to 2.6 W/cm²), nitrogen (N₂) (low-frequency electric power is 0.1 to 0.2 W/cm² and high-frequency electric power is 1.5 to 2.6 W/cm²), or helium (He) (low-frequency electric power is 0.02 W/cm² or less and high-frequency electric power is 1.5 to 2.6 W/cm²). For each inert gas, pressure and time suitable for the sputter etching are 2 to 15 mTorr and 1 to 10 seconds respectively.

A mixed gas which contains two or more of the above inert gases may be used. In addition, a mixed gas which contains Ar and hydrogen (H₂), Kr and H₂, Xe and H₂, or N₂ and H₂ may be used. In this case, the flow rate ratio of H₂ to an inert gas may be set to about 0.5 or less.

The case where Ar is used as an inert gas will now be described.

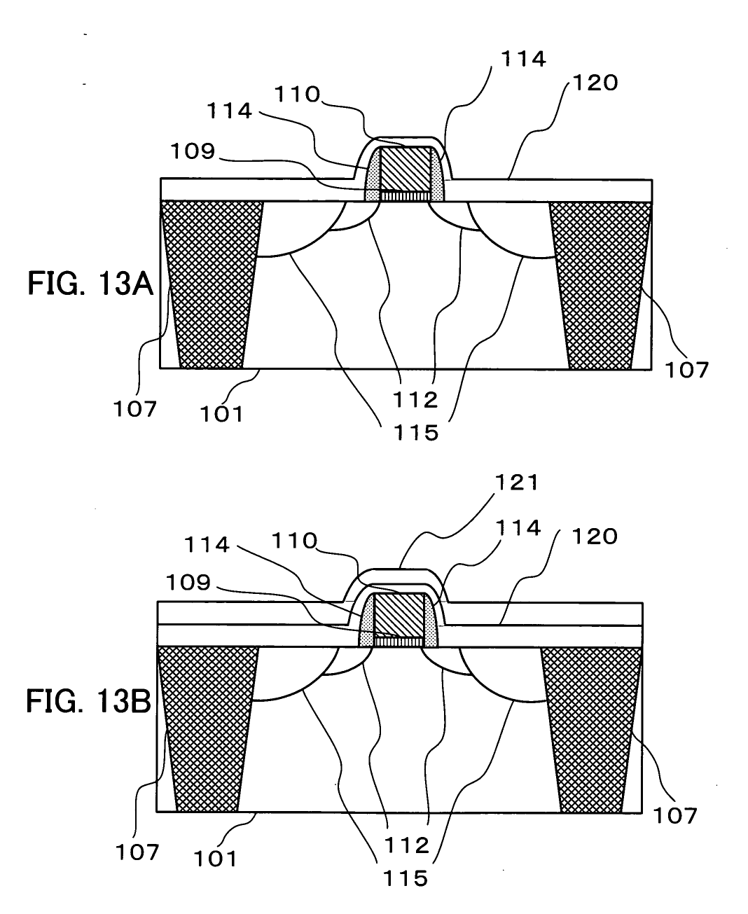

If the sputter etching is performed on, for example, an 8-inch wafer, pressure is 8.0 mTorr, low-frequency electric power is 20 W, high-frequency electric power is 80 W, and time is 5 seconds. Performing the sputter etching under these conditions makes it possible to remove the native oxide film formed on the gate region and the source/drain regions without doing unnecessary damage to the substrate. An Ni film 120 with a thickness of 20 nm is deposited on the semiconductor device on which the sputter etching has been performed by sputtering (FIG. 13A). In this case, the fabrication apparatus 500 shown in FIG. 32 and an Ni target are used and the semiconductor device is not exposed to air. (Before the Ar sputter etching, hydrofluoric acid treatment may be performed to etch the native oxide film by about 1 to 2 nm. A Nickel-platinum (NiPt) mixed target (Pt content is 1 to 10 atom percent) may be used in place of the Ni target for depositing an NiPt film on the substrate. The thickness of the Ni (or NiPt) film 120 is 5 to 200 nm.

A titanium nitride (TiN) film 121 with a thickness of 0 to 50 nm is then deposited as a cap film (FIG. 13B). A titanium (Ti) film with a thickness of 0 to 30 nm may be deposited in place of the TiN film 121. The deposition of a cap film may be omitted.

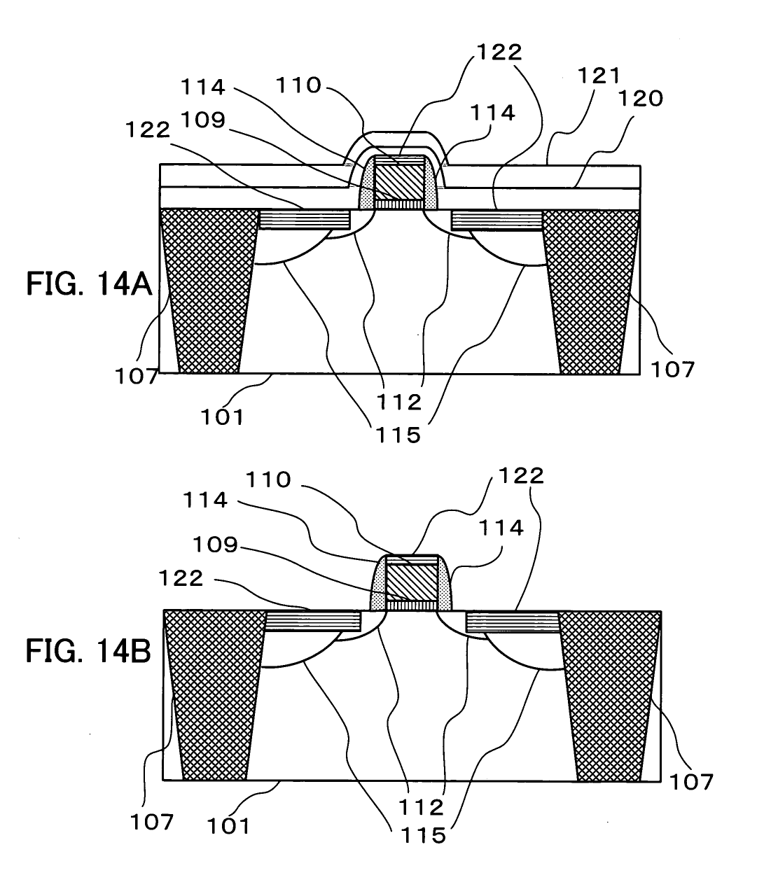

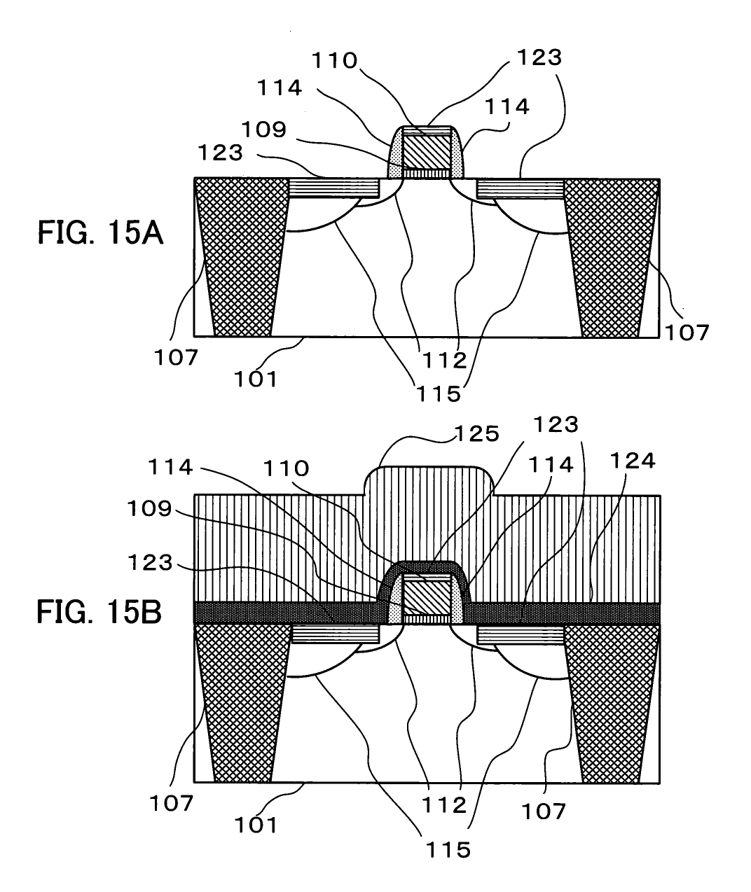

After the TiN film 121 is deposited, first rapid thermal anneal treatment is performed at a temperature of 270° C. for 30 seconds. By doing so, Si and Ni are made to react, and nickel silicide (Ni₂Si) 122 is formed by silicidation (FIG. 14A). In this case, furnace anneal (or furnace anneal and rapid thermal anneal) may be performed in place of the rapid thermal anneal treatment. After the silicidation, the cap film and Ni on the insulating film which has not reacted yet are selectively etched and removed by performing chemical treatment for 20 minutes by the use of a sulfuric acid (H₂SO₄) H₂O₂ mixture solution in which the volume ratio of H₂SO₄ to H₂O₂ is three to one (FIG. 14B). After that, second rapid thermal anneal treatment is performed at a temperature of 400° C. for 30 seconds. The first rapid thermal anneal treatment may be performed at a temperature of 200° C. to 350° C. for 10 to 180 seconds. The second rapid thermal anneal treatment may be performed at a temperature of about 340° C. to 500° C. for about 10 to 120 seconds. Furthermore, the second rapid thermal anneal treatment may be performed at a temperature of about 340° C. to 500° C. by causing H₂ and silicon hydroxide (SiH₄) to flow. The Ni₂Si 122 reacts as a result of the anneal treatment and changes to NiSi 123. The anneal treatment is performed at a temperature of 500° C. or less so that the NiSi 123 will not aggregate (FIG. 15A).

The step of forming a wiring plug is then performed.

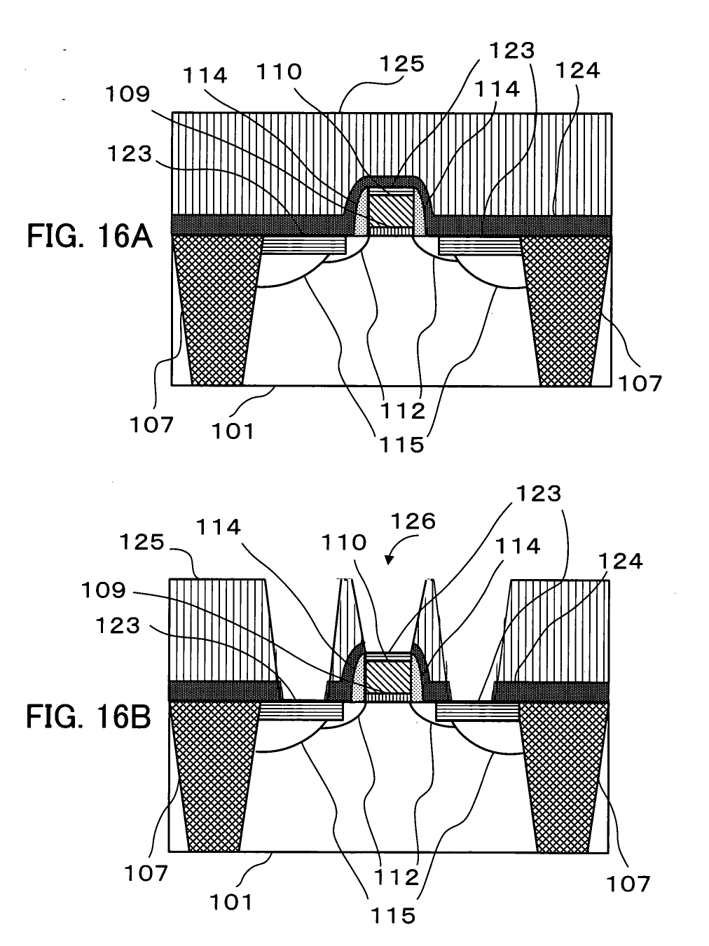

SiN 124 with a thickness of 50 nm is deposited at a temperature of 500° C. by using plasma, and an oxide film 125 with a thickness of 600 nm is deposited at a temperature of 400° C. in the same way (FIG. 15B). After the oxide film 125 is deposited, the oxide film 125 is planarized by the CMP method (FIG. 16A). After the oxide film 125 is planarized, the p-type Si (100) substrate 101 is coated with a photoresist, patterning is performed, and openings 126 are formed by etching (FIG. 16B).

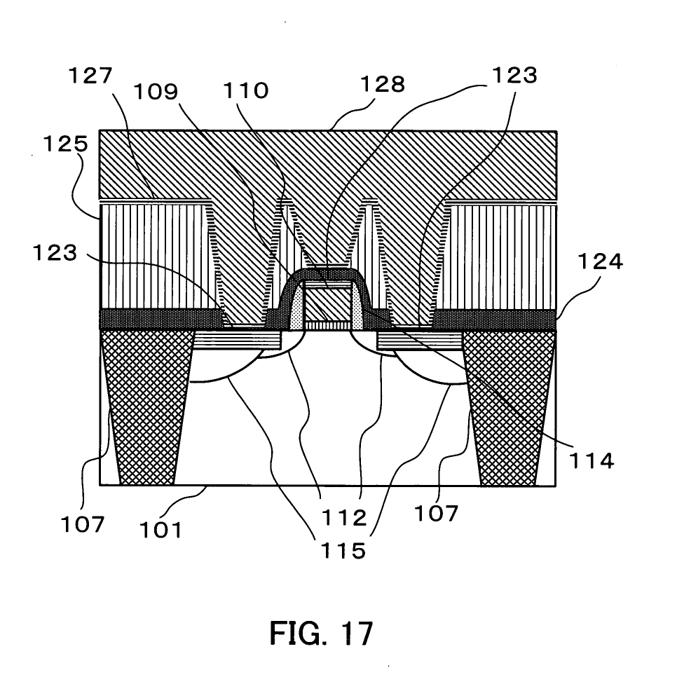

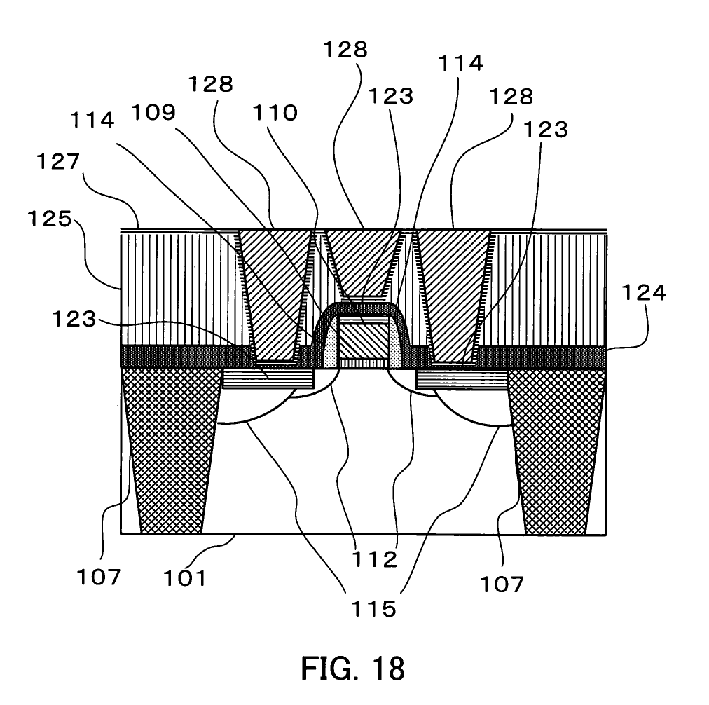

Ti and TiN 127 with thicknesses of 10 nm and 30 nm are then deposited by sputtering. Tungsten (W) 128 with a thickness of 300 nm is deposited by the CVD method to fill up the openings 126 (FIG. 17). The tungsten 128 is planarized by the CMP method (FIG. 18).

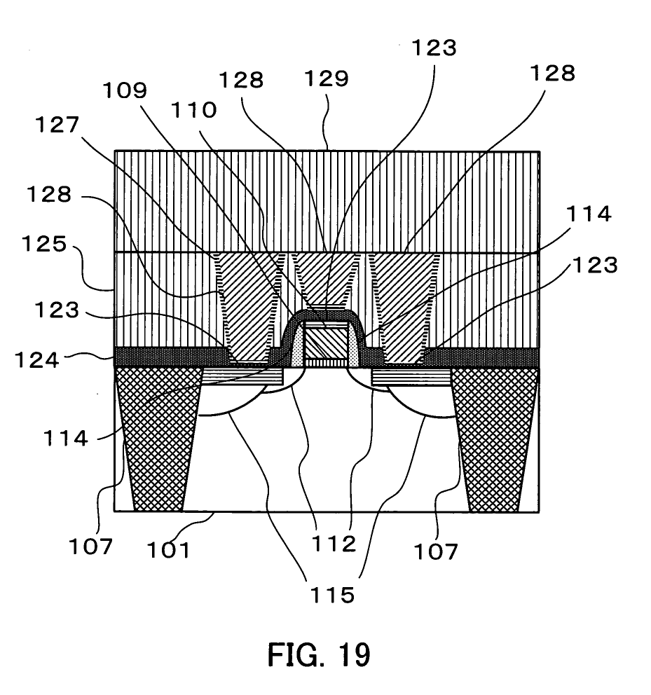

An interlayer film 129 is then deposited and a wiring step is performed (FIG. 19).

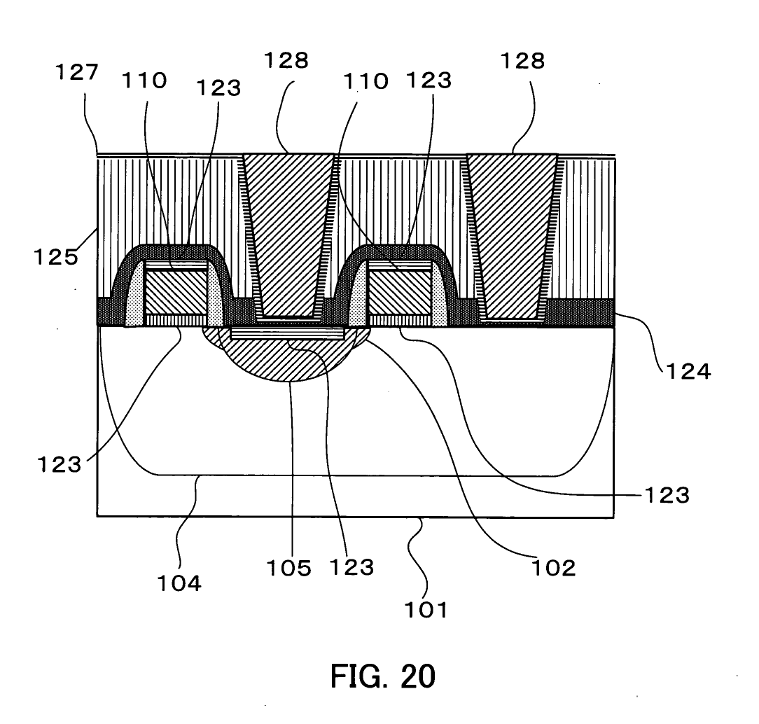

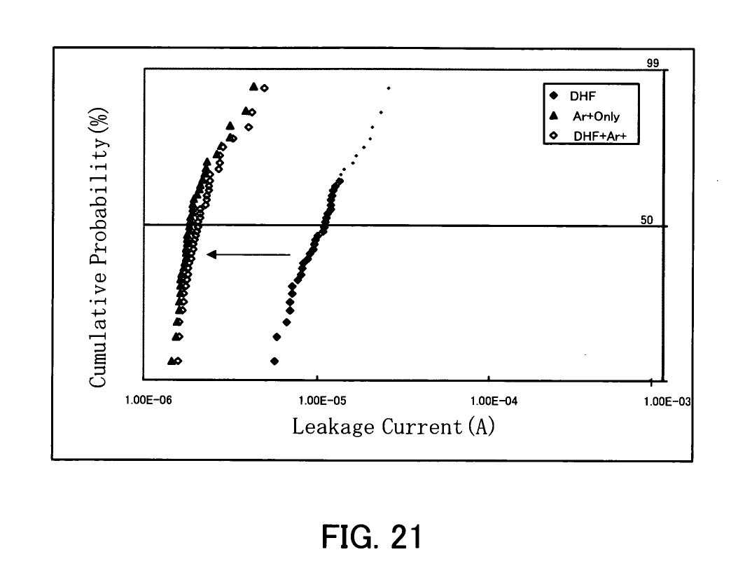

FIG. 20 is a schematic sectional view showing a gate edge enhancement monitor. FIG. 21 shows results obtained by measuring a junction leakage current in gate edge enhancement monitors. The gate edge enhancement monitor shown in FIG. 20 is fabricated by the semiconductor device fabrication method according to the first embodiment of the present invention. A junction leakage current was measured by using a gate edge enhancement monitor fabricated by the semiconductor device fabrication method according to the first embodiment of the present invention in which the Ar sputter etching is performed before the deposition of the NiSi film, a gate edge enhancement monitor fabricated by the semiconductor device fabrication method according to the first embodiment of the present invention in which the hydrofluoric acid treatment and the Ar sputter etching are performed before the deposition of the NiSi film, and a gate edge enhancement monitor fabricated by the conventional semiconductor device fabrication method in which only hydrofluoric acid treatment is performed before the deposition of an NiSi film. As a result, a junction leakage current in the gate edge enhancement monitors fabricated by the semiconductor device fabrication method according to the first embodiment of the present invention is about a tenth of a junction leakage current in the gate edge enhancement monitor fabricated by the conventional semiconductor device fabrication method (FIG. 21).

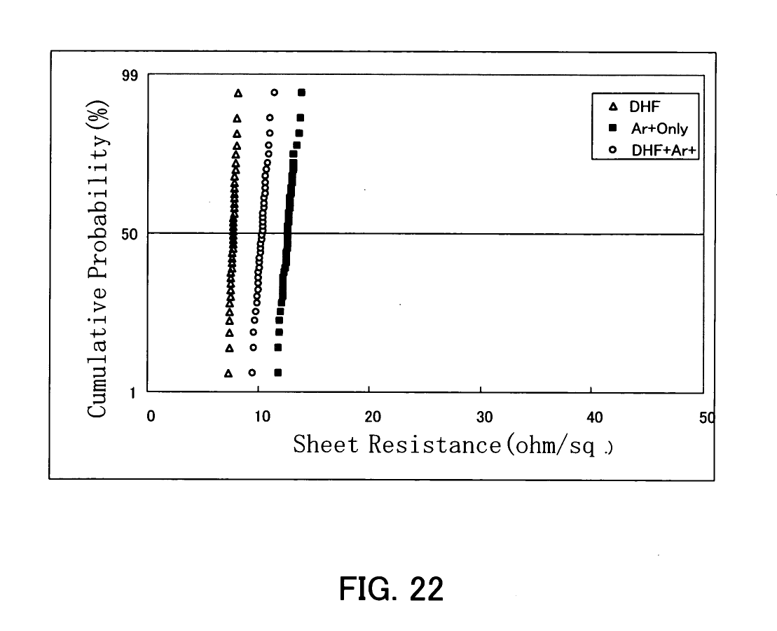

FIG. 22 shows results obtained by measuring the sheet resistance of thin wires included in the gate edge enhancement monitors. As in FIG. 21, the sheet resistance of thin wires included in the three gate edge enhancement monitors was measured. As can be seen from FIG. 22, there is no variation in the sheet resistance of the thin wires included in the gate edge enhancement monitors fabricated by the semiconductor device fabrication method according to the first embodiment of the present invention.

Accordingly, in the semiconductor device fabrication method according to the first embodiment of the present invention the formation of a spike and damage to the substrate are suppressed. As a result, it is possible to reduce a leakage current while keeping variation in the sheet resistance of a thin wire small.

A second embodiment of the present invention will now be described.

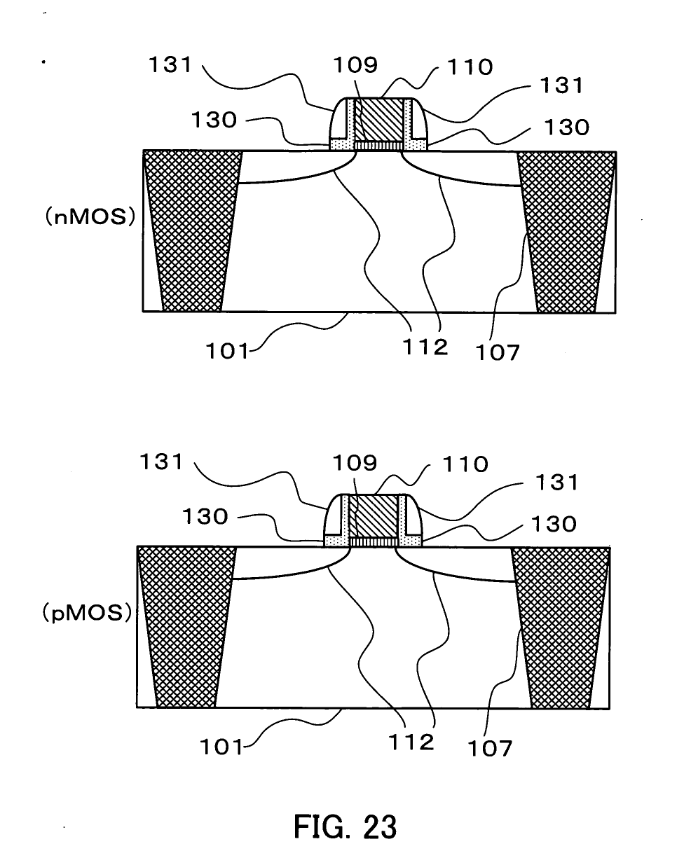

Each of FIGS. 23 through 31 is a sectional view showing a step in a semiconductor device fabrication method according to a second embodiment of the present invention. Descriptions of an nMOS region and a pMOS region will be given. As in the semiconductor device fabrication method according to the first embodiment of the present invention, the fabrication apparatus 500 is used. Unlike the semiconductor device fabrication method according to the first embodiment of the present invention, silicon germanium (SiGe) is used in the PMOS region in the semiconductor device fabrication method according to the second embodiment of the present invention.

The same steps (FIGS. 2A through 10B) that are included in the semiconductor device fabrication method according to the first embodiment of the present invention are used for forming extensions 112. In the nMOS region and the pMOS region, a silicon oxide (SiO) film 130 with a thickness of 10 nm and an SiN film with a thickness of 80 nm are then deposited by the CVD method and side walls 131 are formed by etching (FIG. 23).

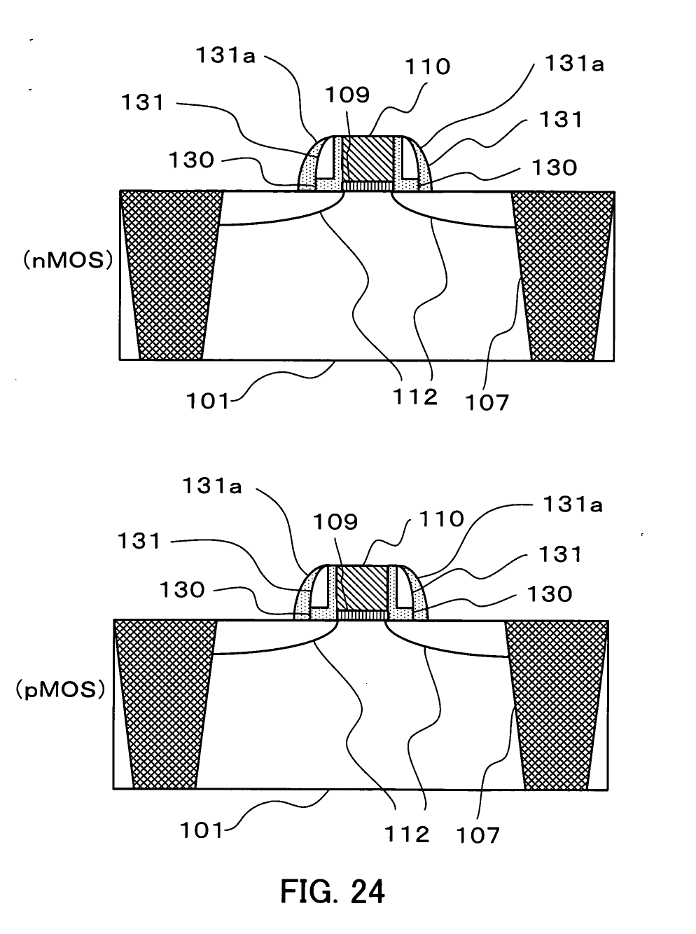

In the nMOS region and the pMOS region, an SiO film with a thickness of 30 nm is then deposited by the CVD method and second side walls 131a are formed (FIG. 24).

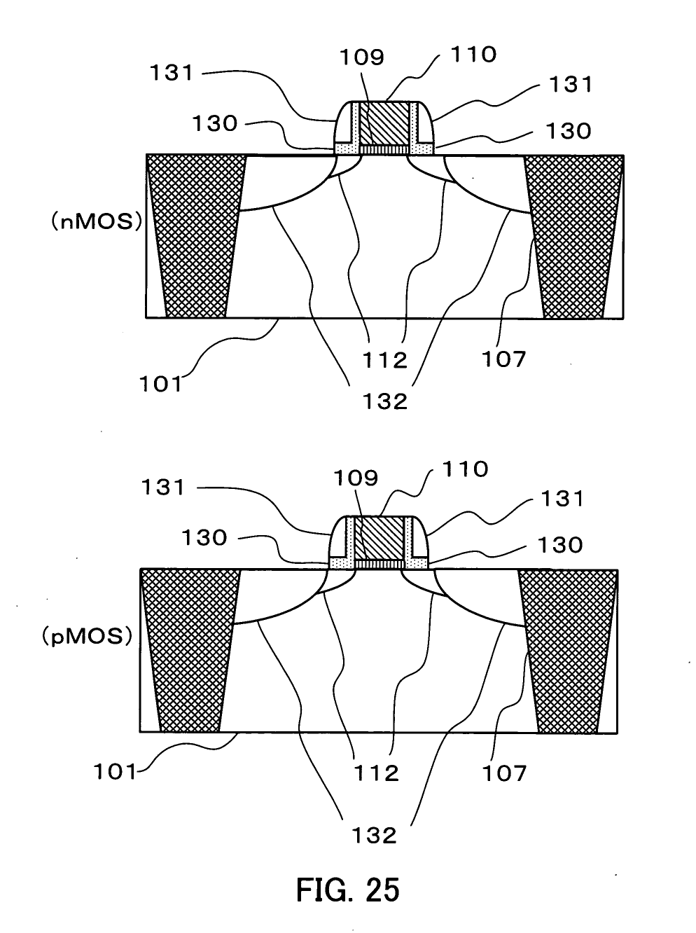

After the second side walls 131a are formed, the second side walls 131a are etched, ion implantation is performed for lowering the resistance of the extensions 112 and forming source/drain regions 132, and activation anneal is performed (FIG. 25).

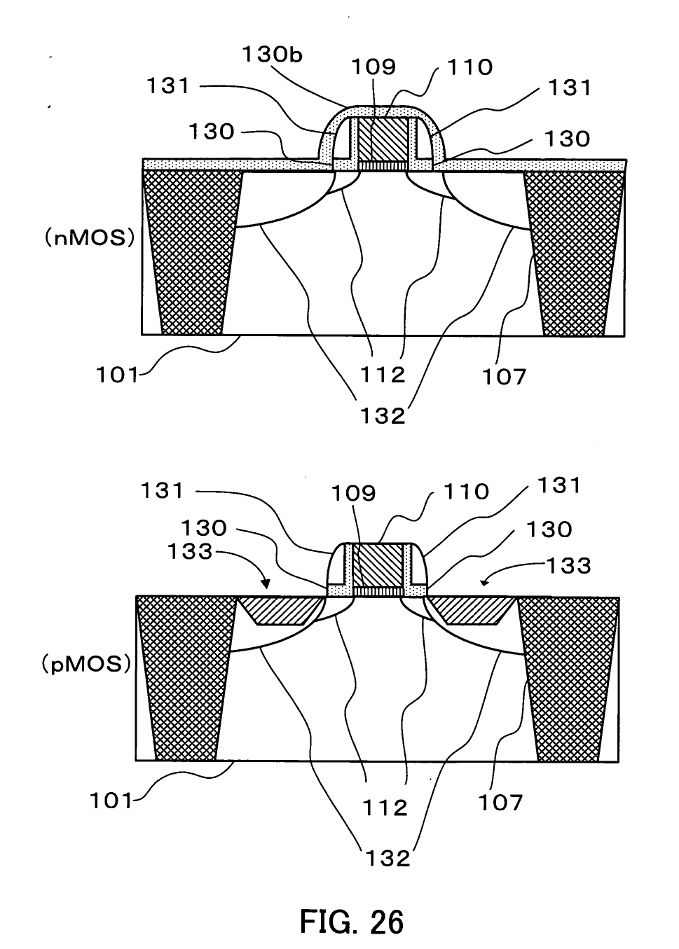

After the activation anneal is performed, the PMOS region is coated with a photoresist and an SiO film 130b is deposited in the nMOS region. In the pMOS region, the photoresist is then removed and portions 133 of the source/drain regions 132 are etched (FIG. 26).

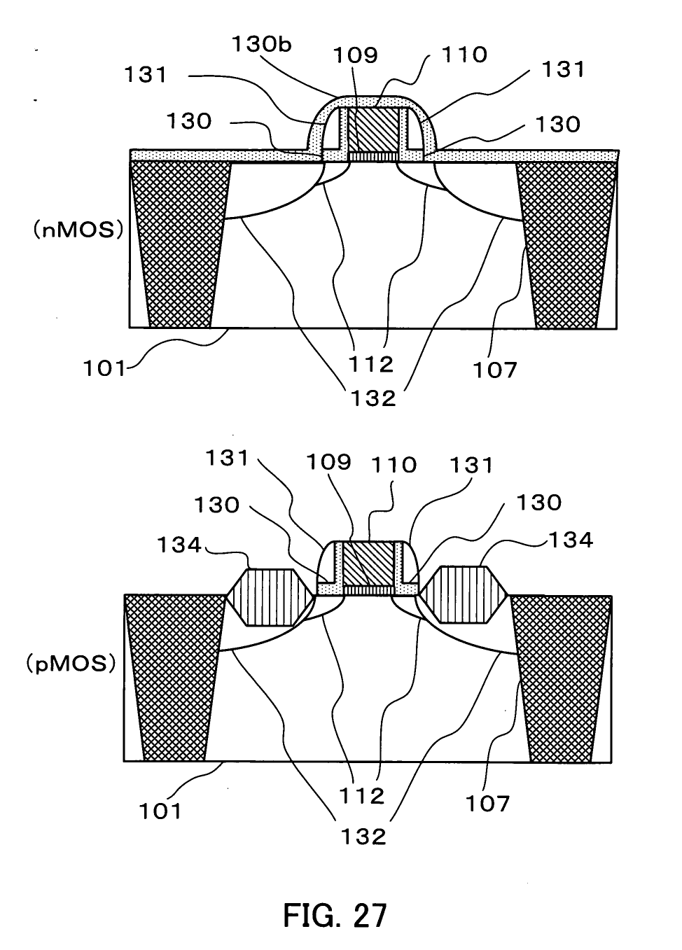

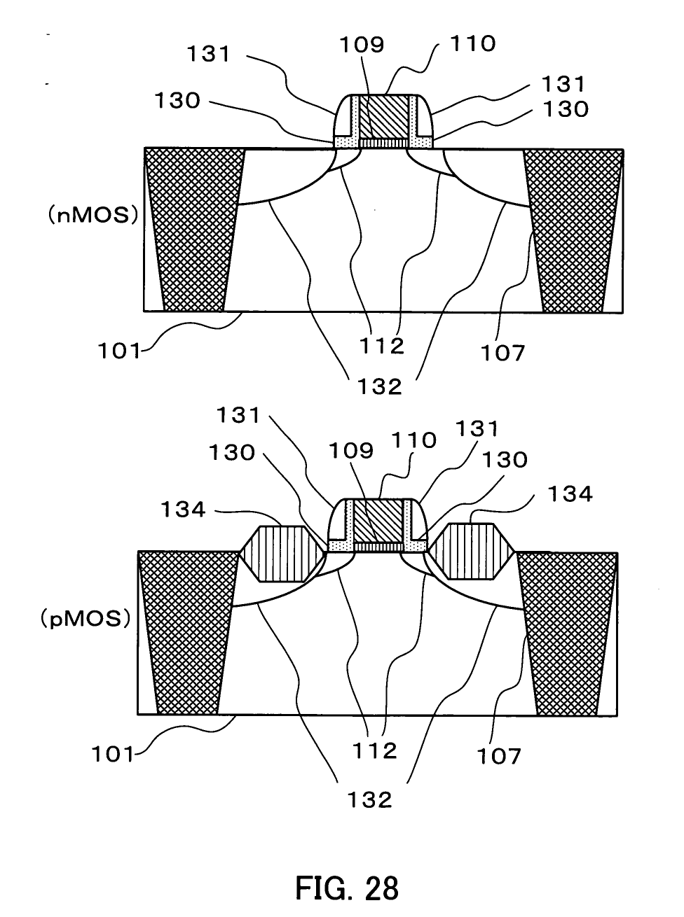

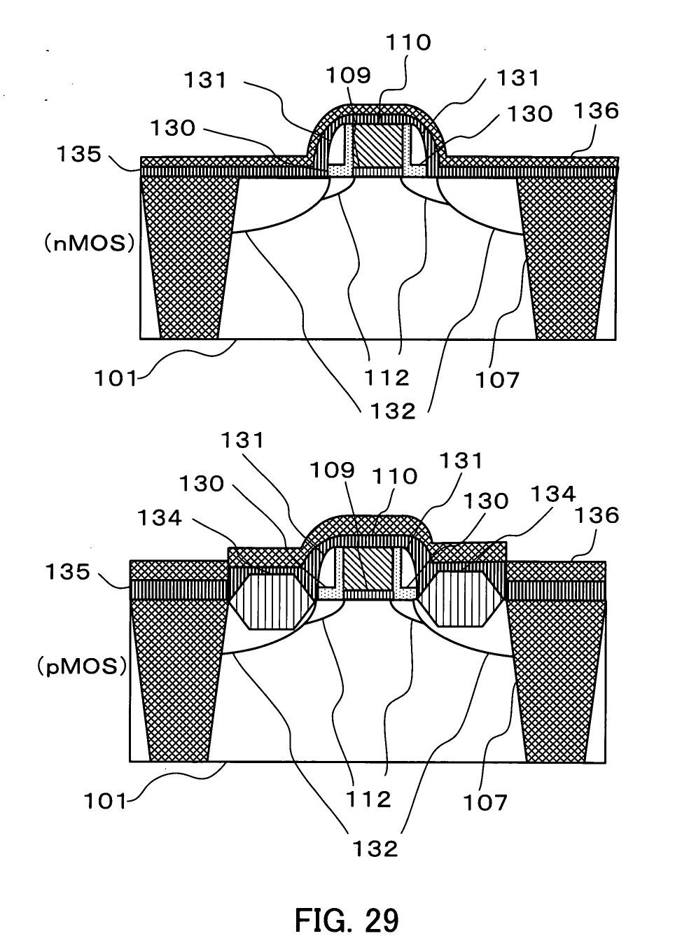

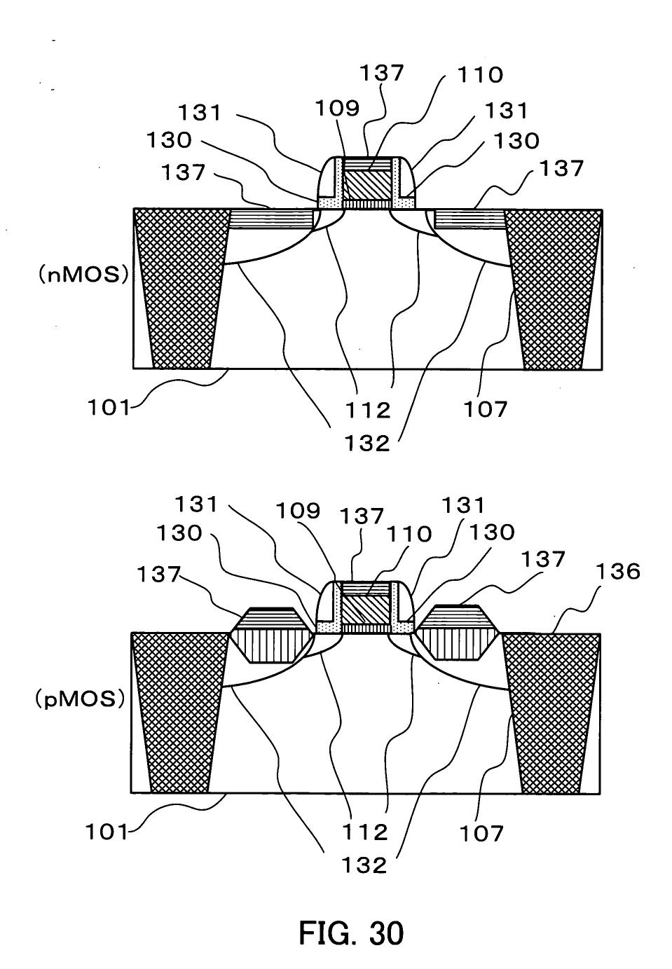

In the PMOS region, SiGe 134 is made to selectively grow (FIG. 27). The SiO film 130b on the nMOS region is removed with hydrofluoric acid (FIG. 28). In the Ar sputter etching chamber 530 included in the fabrication apparatus 500, sputter etching is performed on the surfaces of the nMOS region and the pMOS region for 5 seconds by applying 20 W of low-frequency electric power and 80 W of high-frequency electric power. By doing so, a native oxide film on gate regions and the source/drain regions is removed. An Ni film 135 with a thickness of 20 nm is deposited by sputtering. In this case, an Ni target is used and the nMOS region and the pMOS region are not exposed to air. A TiN film 136 is deposited on the Ni film 135 as a cap film (FIG. 29). This is the same with the semiconductor device fabrication method according to the first embodiment of the present invention. Furthermore, as in the semiconductor device fabrication method according to the first embodiment of the present invention, an NiPt mixed target (Pt content is 1 to 10 atom percent) may be used in place of the Ni target for depositing an NiPt film. The Ni (or NiPt) film must have a thickness of 5 nm or more. Actually, the thickness of the Ni (or NiPt) film is about 200 nm at the most. A Ti film may be used as a cap film in place of the TiN film. In addition, it is not necessary to use a cap film. After the TiN film 136 is deposited, first rapid thermal anneal treatment is performed at a temperature between 220° C. and 280° C. (260° C., for example) for 30 seconds. By doing so, Si and Ni are made to react, and Ni₂Si (not shown) is formed by silicidation. After the silicidation, the TiN cap film and Ni on the insulating film which has not reacted yet are selectively etched by performing chemical treatment for 20 minutes by the use of an H₂SO₄H₂O₂ mixture solution in which the volume ratio of H₂SO₄ to H₂O₂ is three to one. A hydrochloric acid (HCl) H₂O₂ mixture solution may be used in place of an H₂SO₄H₂O₂ mixture solution. After that, second rapid thermal anneal treatment is performed at a temperature of 400° C. for 30 seconds. The second rapid thermal anneal treatment may be performed at a temperature of about 340° C. to 500° C. for about 10 to 120 seconds. Furthermore, the second rapid thermal anneal treatment may be performed at a temperature of about 340° C. to 500° C. by causing H₂ and silicon hydroxide (SiH₄) to flow. The Ni₂Si (not shown) reacts as a result of the anneal treatment and changes to NiSi 137. The anneal treatment is performed at a temperature of 500° C. or less so that the NiSi 137 will not aggregate (FIG. 30).

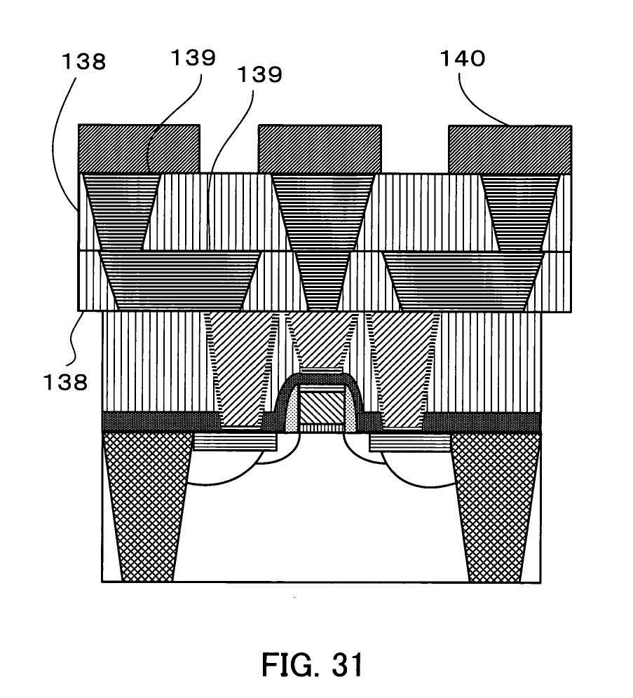

The same steps (FIGS. 15B through 19) that are included in the semiconductor device fabrication method according to the first embodiment of the present invention are then used. Finally, the following wiring step is performed. Dielectric film 138 is deposited, a coating of a photoresist and patterning are performed, and copper (Cu) with tantalum (Ta) barrier 139 is buried. The photoresist and the Cu 139 are planarized by the CMP method and the same step is performed again. By doing so, aluminum (Al) 140 is formed as electrodes (FIG. 31).

By adopting the above semiconductor device fabrication method according to the second embodiment of the present invention, the formation of an NiSiₓ spike and damage to the substrate are suppressed. Therefore, as in the semiconductor device fabrication method according to the first embodiment of the present invention, a leakage current can be reduced.

In the present invention, the native oxide film formed on the surface of the semiconductor substrate where the gate region, the source region, and the drain region are formed is removed by sputter etching in which control is exercised in order to suppress the penetration of the semiconductor substrate by ions to 2 nm or less from the surface. A film of nickel or a nickel compound is formed on the surface of the semiconductor substrate where the native oxide film is removed, and nickel silicide is formed in the gate region, the source region, and the drain region by anneal. This can prevent abnormal diffusion of nickel and reduce damage to the semiconductor substrate. As a result, a junction leakage current can be reduced.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method for fabricating a semiconductor device in which nickel silicide is used as a source electrode and a drain electrode, the method comprising the steps of:
removing by sputter etching a oxide film formed on a surface of a semiconductor substrate where a source region and a drain region are formed, the sputter etching being controlled so as to suppress penetration of the semiconductor substrate by ions to 2 nm or less from the surface;
forming a film of nickel or a nickel compound on the surface from which the oxide film is removed; and
forming nickel silicide in the source region and the drain region by anneal.

2. The method according to claim 1, wherein an inert gas used in the sputter etching is argon, krypton, or xenon.

3. The method according to claim 2, wherein in the sputter etching in which the inert gas is used:
low-frequency electric power applied is 0.1 to 0.4 W for one square centimeter of the semiconductor substrate; and
high-frequency electric power applied is 1.5 to 2.6 W for one square centimeter of the semiconductor substrate.

4. The method according to claim 1, wherein an inert gas used in the sputter etching is nitrogen.

5. The method according to claim 4, wherein in the sputter etching in which the inert gas is used:
low-frequency electric power applied is 0.1 to 0.2 W for one square centimeter of the semiconductor substrate; and
high-frequency electric power applied is 1.5 to 2.6 W for one square centimeter of the semiconductor substrate.

6. The method according to claim 1, wherein an inert gas used in the sputter etching is helium.

7. The method according to claim 6, wherein in the sputter etching in which the inert gas is used:
low-frequency electric power applied is 0.02 W or less for one square centimeter of the semiconductor substrate; and
high-frequency electric power applied is 1.5 to 2.6 W for one square centimeter of the semiconductor substrate.

8. The method according to claim 1, wherein pressure is 2 to 15 mTorr at the time of the sputter etching.

9. The method according to claim 1, wherein the sputter etching is performed for 1 to 10 seconds.

10. The method according to claim 1, wherein an inert gas used in the sputter etching is a mixed gas which contains two or more of argon, krypton, xenon, nitrogen, and helium.

11. The method according to claim 1, wherein a mixed gas in which a flow rate ratio of hydrogen gas to an inert gas is smaller than or equal to 0.5 is used in the sputter etching.

12. The method according to claim 1, wherein the semiconductor device on which the sputter etching is performed is transported to a treatment chamber in which the film of nickel or a nickel compound is formed through a section in which air is evacuated.

13. The method according to claim 1, wherein the anneal is performed at a temperature of 500° C. or less.

14. The method according to claim 1, wherein the sputter etching is performed after silicon germanium is formed in a drain region and a source region of a p-channel MOS transistor region.

15. A method for fabricating a semiconductor device in which nickel silicide is used as a gate electrode, a source electrode, and a drain electrode, the method comprising the steps of:
removing by sputter etching a native oxide film formed on a surface of a semiconductor substrate where a gate region, a source region, and a drain region are formed, the sputter etching being controlled so as to suppress penetration of the semiconductor substrate by ions to 2 nm or less from the surface;
forming a film of nickel or a nickel compound on the surface from which the native oxide film is removed; and
forming nickel silicide in the gate region, the source region, and the drain region by anneal.
